(19) United States
(12) Patent Application Publication
(10) Pub. No.: US 2011/0119565 A1
(43) Pub. Date: May 19, 2011

(54) MULTI-STREAM VOICE TRANSMISSION SYSTEM AND METHOD, AND PLAYOUT SCHEDULING MODULE

(75) Inventors: Yung-Le Chang, Hsinchu (TW); Chun-Feng Wu, Taoyuan County (TW); Wen-Whei Chang, Taoyuan County (TW)

(73) Assignee: GEMTEK TECHNOLOGY CO., LTD., Hukou (TW)

(21) Appl. No.: 12/756,003

(22) Filed: Apr. 7, 2010

(30) Foreign Application Priority Data
Nov. 19, 2009 (TW) 098139304

(51) Int. Cl. H03M 13/05; G10L 19/00; H04L 12/56; G06F 11/10

(52) U.S. Cl. 714/776; 704/201; 370/412; 704/E19.001; 714/E11.032

(57) ABSTRACT

A multi-stream voice transmission system includes a transmitting terminal and a receiving terminal for transmitting and receiving first and second packet streams via first and second network channels. The receiving terminal includes a playout buffer for buffering the first and second packet streams, generates an output voice signal from the buffered packets according to a playout schedule adjusting coefficient β, generates packet loss parameters and packet delay parameters corresponding to loss and delay experienced by the first and second packet streams, and provides the parameters to the transmitting terminal. The transmitting terminal receives the parameters, performs a playout schedule optimizing algorithm employing the parameters so as to determine an optimum value of the playout schedule adjusting coefficient β corresponding to a balanced packet loss rate and a balanced playout delay of the next packets to be transmitted, and provides the playout schedule adjusting coefficient β to the receiving terminal.

### CROSS-REFERENCE TO RELATED APPLICATION

This application claims priority of Taiwanese Application No. 098139304, filed on Nov. 19, 2009.

### BACKGROUND OF THE INVENTION

1. Field of the Invention

The present invention relates to a voice transmission system, more particularly to multi-stream voice transmission system.

2. Description of the Related Art

From the technical aspect of the Voice-over-IP (VoIP) technology, transmitting voice over a packet network requires consideration of packet delay, delay variation, and packet loss. A conventional technique to compensate for delay variation involves implementing a playout buffer in the application layer of a receiving terminal for buffering the received packets so as to control the playout schedule of the received packets. Although the aforesaid technique increases an overall delay of the packets, it reduces packet loss caused by late packet arrival. Therefore, how to reach an equilibrium between the playout schedule of the packets and the corresponding packet loss has become an important topic in the art of packet playout scheduling.

For resistance to packet loss, a transmitting terminal can employ Forward Error Correction (FEC) for appending redundant correction information to an original packet stream such that a receiving terminal may be able to recover lost packets using the redundant correction information. However, FEC introduces an extra delay since the receiving terminal needs to receive both the original packet stream and the appended redundant correction information before the packets of the original packet stream can be recovered from possible lost packets and be processed. Besides, in case of a bursty network loss, the receiving terminal may not be able to receive the original packets and the redundant FEC information such that lost packets cannot be recovered.

In recent years, several studies have proposed Multiple Description Coding (MDC), which is a technique that fragments a single stream of packets into multiple substreams of packets that are routed from a transmitting terminal to a receiving terminal via a corresponding number of mutually independent routes. When one or more of the substreams are lost, the receiving terminal is able to compensate for the lost substreams through combining the contents of the received substreams. Therefore, the quality of voice playout at the receiving terminal can be improved without compromising the overall delay.

Moreover, the International Telecommunication Union Telecommunication Standardization Sector (ITU-T) further specifies a voice quality estimating model, which is referred to as the “E model” (ITU-T G.107), for communication system planning and system key component adjustment. Nevertheless, the model was designed to predict the quality of voice streaming in a Single Description (SD) system, and is not used to estimate the quality of voice streaming in a Multiple Description (MD) system.

### SUMMARY OF THE INVENTION

Therefore, an object of the present invention is to provide a multi-stream voice quality prediction model and to develop a multi-stream voice transmission system based thereon.

Accordingly, a multi-stream voice transmission system of the present invention is adapted for transmitting and receiving voice signals through first and second network channels, and comprises a transmitting terminal and a receiving terminal.

The transmitting terminal is configured to process an input voice signal so as to generate first and second packet streams, and to transmit the first and second packet streams via the first and second network channels, respectively. The transmitting terminal includes a voice encoder, a multiple description (MD) encoding unit including a MD encoder, and a playout scheduling module.

The voice encoder is for encoding the input voice signal into a plurality of source frames. The MD encoding unit is for encoding the source frames into the first and second packet streams. The playout scheduling module is configured to obtain a playout schedule adjusting coefficient (β) corresponding to the first and second packet streams to be transmitted.

The receiving terminal is configured to receive the first and second packet streams transmitted by the transmitting terminal via the first and second network channels, to process the first and second packet streams so as to generate an output voice signal, and to receive the playout schedule adjusting coefficient (β) from the transmitting terminal. The receiving terminal includes a network information recording module, a MD decoding unit, and a voice decoder.

The network information recording module is for recording information regarding network delay and network loss experienced by the packets in the first and second packet streams transmitted via the first and second network channels, for generating network delay parameters and network loss parameters according to the recorded information, and for providing the network delay parameters and the network loss parameters to the playout scheduling module of the transmitting terminal.

The MD decoding unit is for receiving the first and second packet streams, and includes a MD decoder including a playout buffer for buffering packets corresponding to the first and second packet streams. The MD decoder generates a plurality of recovered frames from the packets buffered by the playout buffer according to the playout schedule adjusting coefficient (β) received from the transmitting terminal.

The voice decoder is for generating the output voice signal from the recovered frames.

The voice encoder and the MD encoding unit of the transmitting terminal collectively introduce a coding delay (dc) to the multi-stream voice transmission system.

The playout schedule adjusting coefficient (β) obtained by the playout scheduling module has a value within a preset range that results in a maximum value of a quality parameter (R), the quality parameter (R) being equal to 94.2−Iₑ−I_{D}(D). Iₑ is a function of the playout schedule adjusting coefficient (β), and the network delay parameters and the network loss parameters received from the receiving terminal. I_{D}(D) is a function of the coding delay (dc), the playout schedule adjusting coefficient (β), and the network delay parameters.

Preferably, the MD encoder of the MD encoding unit is for encoding the source frames into first and second encoded MD packet streams at packetization intervals (Tₚ).

Preferably, the MD encoding unit of the transmitting terminal further includes first and second forward error correction (FEC) encoders coupled to the MD encoder for performing FEC encoding upon the first and second encoded MD packet streams so as to generate the first and second packet streams at packetization intervals (T_{P}), respectively. Each of the first and second packet streams includes a plurality of FEC blocks, and each of the FEC blocks includes K packets and (N−K) check packets that are generated for the K packets.

Preferably, the MD decoding unit of the receiving terminal further includes first and second FEC decoders for performing FEC decoding upon the first and second packet streams received via the first and second network channels so as to generate first and second decoded MD packet streams, respectively.

Preferably, the playout buffer of the MD decoder is coupled to the first and second FEC decoders for receiving the first and second decoded MD packet streams and for buffering the first and second decoded MD packet streams.

Preferably, the input voice signal is constituted by a plurality of talkspurts with a silence period between temporally adjacent ones of the talkspurts.

Preferably, the playout scheduling module is configured to obtain, from the network delay parameters, the network loss parameters, and the coding delay (dc), a combination of values of N, K and the playout schedule adjusting coefficient (β) corresponding to the first and second packet streams to be transmitted. Preferably, N, K and the playout schedule adjusting coefficient (β) obtained by the playout scheduling module have values within corresponding preset ranges that result in the maximum value of the quality parameter (R) and that satisfy a condition that a product of N/K and MD coding gain is less than 2 and a condition that K is greater than a number of packets of the next talkspurt to be transmitted.

Preferably, Iₑ is a function of N, K, the playout schedule adjusting coefficient (β), the network delay parameters, and the network loss parameters. I_{D}(D) is a function of N, the packetization interval (Tₚ), the playout schedule adjusting coefficient (β), the coding delay (dc), and the network delay parameters.

Preferably, the playout scheduling module is configured to provide N and K obtained thereby to the first and second FEC encoders.

Another object of the present invention is to provide a multi-stream voice transmission method for transmitting and receiving voice signals through first and second network channels. The multi-stream voice transmission method includes the steps of:

(A) configuring a transmitting terminal to process an input voice signal so as to generate first and second packet streams, and to transmit the first and second packet streams via the first and second network channels, respectively, including
(A1) configuring the transmitting terminal to perform voice encoding so as to encode the input voice signal into a plurality of source frames,
(A2) configuring the transmitting terminal to encode the source frames into the first and second packet streams, the encoding in sub-step (A2) including multiple description (MD) encoding, and
(A3) configuring the transmitting terminal to obtain a playout schedule adjusting coefficient (β) corresponding to the first and second packet streams to be transmitted; and

(B) configuring a receiving terminal to receive the first and second packet streams transmitted by the transmitting terminal via the first and second network channels, to process the first and second packet streams so as to generate an output voice signal, and to receive the playout schedule adjusting coefficient (β) from the transmitting terminal, including
(B1) configuring the receiving terminal to record information regarding network delay and network loss experienced by packets in the first and second packet streams transmitted via the first and second network channels, to generate network delay parameters and network loss parameters according to the recorded information, and to provide the network delay parameters and the network loss parameters to the transmitting terminal,
(B2) configuring the receiving terminal to buffer packets corresponding to the first and second packet streams in a playout buffer, and to perform MD decoding of the packets buffered by the playout buffer according to the playout schedule adjusting coefficient (β) obtained from the transmitting terminal so as to generate a plurality of recovered frames, and
(B3) configuring the receiving terminal to perform voice decoding for generating the output voice signal from the recovered frames.

In step (A), the transmitting terminal introduces a coding delay (dc).

In sub-step (A3), the playout schedule adjusting coefficient (β) obtained by the transmitting terminal has a value within a preset range that results in a maximum value of a quality parameter (R), the quality parameter (R) being equal to 94.2−Iₑ−I_{D}(D)

Iₑ is a function of the playout schedule adjusting coefficient (β), and the network delay parameters and the network loss parameters received by the transmitting terminal from the receiving terminal. I_{D}(D) is a function of the coding delay (dc), the playout schedule adjusting coefficient (β), and the network delay parameters.

Preferably, in sub-step (A2), the source frames are encoded into first and second encoded MD packet streams at packetization intervals (Tₚ).

Preferably, the encoding in sub-step (A2) further includes forward error correction (FEC) encoding upon the first and second encoded MD packet streams so as to generate the first and second packet streams at packetization intervals (Tₚ), respectively, each of the first and second packet streams including a plurality of FEC blocks, each of the FEC blocks including K packets and (N−K) check packets that are generated for the K packets.

Preferably, sub-step (B2) further includes performing FEC decoding upon the first and second packet streams received via the first and second network channels so as to generate first and second decoded MD packet streams, respectively.

Preferably, in sub-step (B2), the playout buffer receives the first and second decoded MD packet streams for buffering the first and second decoded MD packet streams.

Preferably, in sub-step (A1), the input voice signal is constituted by a plurality of talkspurts with a silence period between temporally adjacent ones of the talkspurts.

Preferably, in sub-step (A3), the transmitting terminal is configured to obtain, from the network delay parameters, the network loss parameters, and the coding delay (dc), a combination of values of N, K and the playout schedule adjusting coefficient (β) corresponding to the first and second packet streams to be transmitted. Preferably, N, K and the playout schedule adjusting coefficient (β) obtained by the transmitting terminal have values within corresponding preset ranges that result in the maximum value of the quality parameter (R) and that satisfy a condition that a product of N/K and MD coding gain is less than 2 and a condition that K is greater than a number of packets of the next talkspurt to be transmitted.

Preferably, Iₑ is a function of N, K, the playout schedule adjusting coefficient (β), the network delay parameters, and the network loss parameters. Preferably, I_{D}(D) is a function of N, the packetization interval (Tₚ), the playout schedule adjusting coefficient (β), the coding delay (dc) and the network delay parameters.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic system block diagram illustrating the first preferred embodiment of a multi-stream voice transmission system according to the present invention;

FIG. 2 is a flowchart illustrating the first preferred embodiment of a voice quality optimization scheme according to the present invention;

FIG. 3 is a schematic diagram illustrating recovered frames of a talkspurt as recovered by a MD decoder of a MD decoding unit of a receiving terminal of the multi-stream voice transmission system of the first preferred embodiment;

FIG. 4 is a schematic system block diagram illustrating the second preferred embodiment of a multi-stream voice transmission system according to the present invention; and

FIG. 5 is a flowchart illustrating the second preferred embodiment of a voice quality optimization scheme according to the present invention.

### DETAILED DESCRIPTION OF THE PREFERRED EMBODIMENT

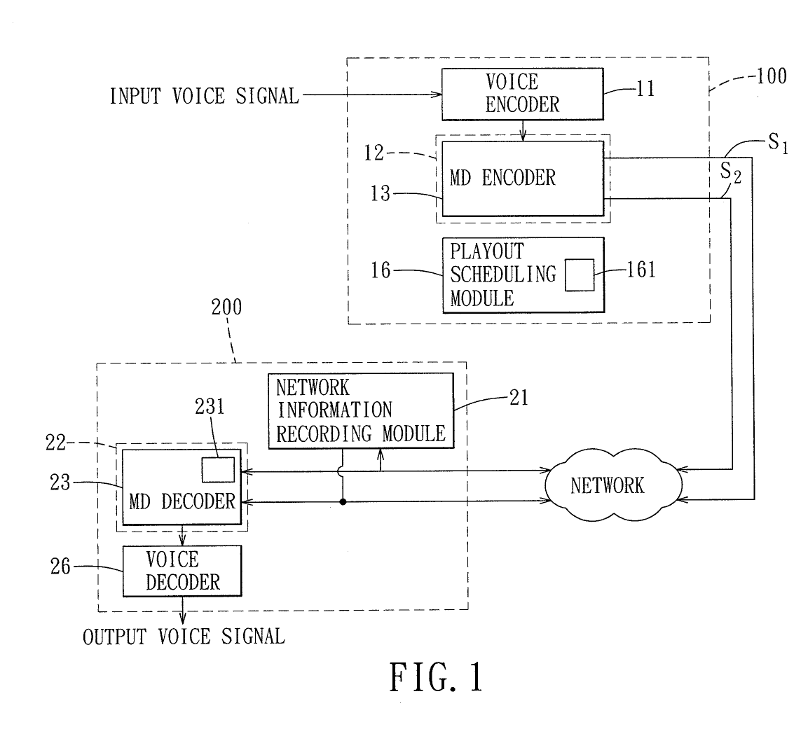

Referring to FIG. 1, the first preferred embodiment of a multi-stream voice transmission system according to the present invention is adapted for transmitting and receiving voice signals through first and second network channels, and includes a transmitting terminal 100 and a receiving terminal 200.

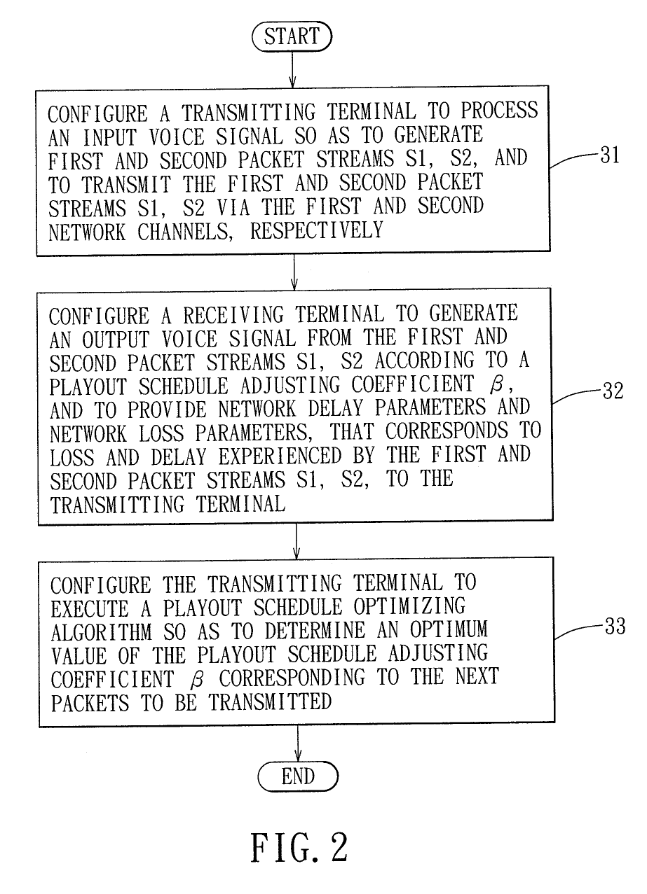

FIG. 2 shows a flowchart of the first preferred embodiment of a voice quality optimization scheme according to present invention. The multi-stream voice transmission system of the first preferred embodiment is configured to perform the voice quality optimization scheme.

In Step 31 of the voice quality optimization scheme, the transmitting terminal 100 is configured to process an input voice signal so as to generate first and second packet streams S1, S2, and to transmit the first and second packet streams S1, S2 via the first and second network channels, respectively. In this embodiment, the transmitting terminal 100 includes a voice encoder 11, a Multiple Description (MD) encoding unit 12, and a playout scheduling module 16.

The voice encoder 11 of the transmitting terminal 100 is for encoding an input voice signal. In most VoIP applications, speech can be divided into two parts—talkspurts and silence periods. For example, the sentence, “I am xxx”, consists of three talkspurts and two silence periods. Furthermore, the voice encoder 11 of the present embodiment employs one of the G.729a and the AMR-WB voice encoding standards for encoding each talkspurt of the input voice signal into a plurality of source frames.

The MD encoding unit 12 is for encoding the source frames into the first and second packet streams S1, S2, and includes a MD encoder 13.

The voice encoder 11 and the MD encoding unit 12 collectively introduce a coding delay (dc) to the multi-stream voice transmission system.

The playout scheduling module 16 is configured to receive network delay parameters and network loss parameters and to obtain, from the network delay parameters, the network loss parameters, and the coding delay (dc), a playout schedule adjusting coefficient (β) corresponding to the next packets of the first and second packet streams S1, S2 to be transmitted. Details of the network delay parameters and the network loss parameters can be found in the succeeding paragraphs.

The receiving terminal 200 is configured to receive the first and second packet streams S1, S2 transmitted by the transmitting terminal 100 via the first and second network channels, to process the first and second packet streams S1, S2 so as to generate an output voice signal, and to receive the playout schedule adjusting coefficient (β) from the transmitting terminal 100, such as via at least one of the first and second network channels. The receiving terminal 200 includes a network information recording module 21, a MD decoding unit 22, and a voice decoder 26.

The MD decoding unit 22 is for receiving the first and second packet streams S1, S2, for generating a plurality of recovered frames from the first and second packet streams S1, S2, and includes a MD decoder 23 including a playout buffer 231 for buffering packets corresponding to the first and second packet streams S1, S2, thereby improving tolerance of the multi-stream voice transmission system for the time-varying characteristics of the network. The MD decoder 23 is for generating the plurality of recovered frames from the packets buffered by the playout buffer 231 according to the playout schedule adjusting coefficient (β) received from the transmitting terminal 200.

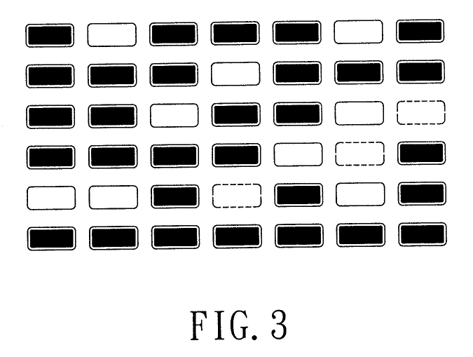

FIG. 3 shows forty-two recovered frames (G.729a) generated by the MD decoder 23.

Each of the solid frames represents a recovered frame for which the MD decoding unit 22 successfully buffers and decodes the packets of each of the first and second packet streams S1, S2 that correspond to the frame (Ω₁). Each of the solid-bordered empty frames represents a recovered frame for which the MD decoding unit 22 successfully buffers and decodes the packets of only one of the first and second packet streams S1, S2 that correspond to the frame (Ω₂). Each of the dash-bordered empty frames represents an unrecoverable frame for which none of the packets of the first and second packet streams S1, S2 that correspond to the frame (Ω₃) was successfully buffered and decoded by the MD decoding unit 22.

The voice decoder 26 is for generating the output voice signal from the recovered frames.

In Step 32 of the first preferred embodiment of the voice quality optimization scheme, the network information recording module 21 is configured to record information regarding network delay and network loss experienced by the packets of the first and second packet streams S1, S2 during the transmission process, to generate the network delay parameters and the network loss parameters from the recorded information, and to provide the network delay parameters and the network loss parameters to the playout scheduling module 16 of the transmitting terminal 100.

The network delay parameters generated by the network information recording module 21 are for describing the network delay experienced by the packets, and include Pareto distribution parameters (kₛ and gₛ), a network delay cumulative function F_{D,S}(D), an estimated network delay \hat{d}_{i,s}, and an estimated network delay variation \hat{ν}_{i,s}. The network loss parameters generated by the network information recording module 21 are for describing the network loss experienced by the packets, and include Gilbert channel model parameters (pₛ, qₛ) for describing the network loss.

The network information recording module 21 of the receiving terminal 200 is configured to obtain the estimated network delay \hat{d}_{i,s}, and the estimated network delay variance \hat{ν}_{i,s} using an Autoregressive (AR) method, which is described as follows:

d_{play,i}=\hat{d}ᵢ+β\hat{ν}ᵢ

\hat{d}_{i,s}=α\hat{d}_{i-1,s}+(1+α)n_{i-1,s}

\hat{ν}_{i,s}=α\hat{ν}_{i-1,s}+(1−α)|n_{i-1,s}−\hat{d}_{i-1,s}|

wherein:
\hat{d}_{i,s}, \hat{d}_{i-1,s}, and n_{i-1,s} are the estimated network delay of the i^{th} packet (i.e., the next packet to be transmitted), the estimated network delay of the (i−1)^{th} packet, and the actual measured network delay of the (i−1)^{th} packet, respectively, corresponding to the first and second packet streams S1 (s=1), S2 (s=2),
\hat{ν}_{i,s} and \hat{ν}_{i-1,s} are the estimated network delay variance of the i^{th} packet and the estimated network delay variance of the (i−1)^{th} packet, respectively, corresponding to the first and second packet streams S1, S2,
α is a predetermined coefficient and is 0.998002 in the present embodiment,
d_{play,i} is the playout delay of the i^{th} packets of the first and second packet streams S1, S2, and is defined as the time interval between a packet being transmitted by the transmitting terminal 100 and the packet, which is subsequently buffered by the playout buffer 231 of the MD decoder 23, being processed by the MD decoder 23, and
the playout schedule adjusting coefficient β is a coefficient for including the effect of the buffer delay in the playout delay d_{play,i} by adjusting the estimated network variance \hat{ν}_{i,s}. In other words, the playout delay d_{play,i} is the sum of the estimated network delay and the buffer delay.

It is to be noted that the network delay cumulative distribution function F_{D,s}(D) and the Pareto distribution parameters kₛ, gₛ are related to each other by the following mathematical relation:

F_{D,s}(D)=1−(kₛ/D)^{gs} for D≧kₛ,

hence, F_{D,s}(D) can be obtained given kₛ and gₛ, and vice versa.

The network information recording module 21 transmits the network delay parameters (kₛ, gₛ, F_{D,S}(D), \hat{d}_{i,s} and \hat{ν}_{i,s}) and the network loss parameters (pₛ and qₛ) to the playout scheduling module 16 of the transmitting terminal 100, such as via at least one of the first and second network channels, before the transmitting terminal 100 transmits the next talkspurt.

In Step 33 of the voice quality optimization scheme, after receiving from the network information recording module 21 the network delay parameters and the network loss parameters corresponding to the last packets of the first and second packet streams S1, S2 received by the receiving terminal 200, the playout scheduling module 16 is configured to execute a playout schedule optimizing algorithm so as to determine an optimum value of the playout schedule adjusting coefficient (β) corresponding to the next packets to be transmitted.

The algorithm is described as follows:

R=94.2−Iₑ(e)−I_{D}(D),

wherein:
R is a quality parameter that represents, and is directly proportional to, the predicted quality of the output voice signal corresponding to the next packets to be transmitted,
e is a probability of the next packets of the first and second packet streams S1, S2 to be transmitted being lost during the transmission (unplayable), and a description of which is given hereinafter,
Iₑ(e) is an encoding and loss impairment prediction model for describing impairment of the quality of the output voice signal due to packet encoding and packet loss, and takes into consideration the playout schedule adjusting coefficient (β), the network delay parameters (kₛ, gₛ, F_{D,S}(D), \hat{d}_{i,s} and \hat{ν}_{i,s}), and the network loss parameters (pₛ and qₛ),
D is the overall delay of the multi-stream voice transmission system, and is the sum of the playout delay d_{play,i} and the coding delay (dc), D=d_{play,i}+dC, and
I_{D}(D) is a delay impairment prediction model for describing impairment of the quality of the output voice signal due to the overall delay, and takes into consideration the playout schedule adjusting coefficient (β), the coding delay (dc), and the estimated network delay \hat{d}_{i,s} and the estimated network delay variation \hat{ν}_{i,s}.

Furthermore, the playout schedule adjusting coefficient (β) obtained by the playout scheduling module 16 has a value within a corresponding preset range that results in the maximum value of the quality parameter R.

The playout schedule optimizing algorithm is implemented using a program executable by a computing unit 161 of the playout scheduling module 16. The following is the flow of the program (“//” indicates a comment):

Initial: R₁=0; R₂=0;

FOR β_{search}=βₘᵢₙ:u:βₘₐₓ //sets the search range of the playout schedule adjusting coefficient (β), where u is an incremental step of each successive search (e.g., βₘᵢₙ:u:βₘₐₓ=1:0.5:10)
//the algorithm obtains a value of the playout schedule adjusting coefficient (β) corresponding to the next packet of the first packet stream S1 to be transmitted
D=d_{play,i}+dc=\hat{d}_{i,1}+β_{search}×\hat{ν}_{i,1}+dc //obtains an estimated overall delay of the system
I_{D}(D)=0.024D+0.11(D−177.3)H(D−177.3) //obtains a delay impairment prediction value using the delay impairment prediction model I_{D}(D), wherein H is a step function

I_{e,temp}=Iₑ(β_{search},p₁,q₁,F_{D,1}(D),(k₁,g₁),p₂,q₂,F_{D,2}(D),k₂,g₂),\hat{d}_{i,2},\hat{ν}_{i,2)}

//obtains an encoding and loss impairment prediction value using the encoding and loss impairment prediction model Iₑ(e), the description of which is given hereinafter
R₁_{_{—}}ₜₑₘₚ=94.2−I_{D}(D)−T_{e,temp} //obtains a value of R₁ corresponding to the current value of β in the current search
IF R₁_{_{—}}ₜₑₘₚ>R₁ // if the value of R₁ obtained in the current search is greater than a temporary maximum value of R₁ obtained in the preceding search
   R₁=R₁_{_{—}}ₜₑₘₚ; //the value of R₁ in the current search becomes the temporary maximum value of R₁
   β_{—}_{¹}=β_{search}; //records the value of β corresponding to the temporary maximum value of R₁
END IF
// next, the algorithm obtains a value of the playout schedule adjusting coefficient β corresponding to the next packet of the second packet stream S2 to be transmitted

D=d_{play,i}+dc=\hat{d}_{i,2}+β_{search}×\hat{ν}_{i,2}+dc

I_{d}(D)=0.024D+0.11(D−177.3)H(D−177.3)

I_{e,temp}=Iₑ(β_{search},p₁,q₁,F_{D,1}(D),(k₁,q₁),p₂,q₂,F_{D,2}(D),(k₂,g₂),\hat{d}_{i,2},\hat{ν}_{i,2)}

R₂_{_{—}}ₜₑₘₚ=94.2−I_{d}(D)−I_{e,temp}

IF R₂_{_{—}}ₜₑₘₚ>R₂

R₂=R₂_{_{—}}ₜₑₘₚ;

β_{—}_{²}=β_{search};
END IF

END //the algorithm has found two optimum values of β (namely, β_{—}_{¹} and β_{—}_{²}) corresponding to the next packets of the first and second packet streams S1, S2 to be transmitted, respectively; however, the same playout schedule adjusting coefficient β needs to be used by the MD decoding unit 22 for processing the next packets; subsequently, the algorithm will choose one of β_{—}_{¹} and β_{—}_{²} that corresponds to a higher value of the quality parameter R

IF R₁>R₂ // if R₁ is greater than R₂
β=β_{—}_{¹} //the value of β is equal to β_{—}_{¹}
d_{play,i}=\hat{d}_{i,1}+β×\hat{ν}_{i,1} //obtains a playout delay d_{play,i} corresponding to β_{—}_{¹}

ELSE //or else
β=β_{—}_{²}// the value of β is equal to β_{—}_{²}
d_{play,i}=\hat{d}_{i,2}+β×\hat{ν}_{i,2} //obtains a playout delay

d_{play,i} corresponding to β_{—}_{²}

END IF

After executing the program, the playout scheduling module 16 is further configured to provide the playout schedule adjusting coefficient (β) obtained thereby to the MD decoder 23 such that the MD decoder 23 can generate the recovered frames from the buffer packets according to the playout schedule adjusting coefficient (β).

### Determining Value of Iₑ(e)

The encoding and loss impairment prediction model Iₑ(e) is described as follows:

$${I}_{e} ( e ) = {\sum }_{j = 1}^{2} {ρ}_{j} {I}_{e , j} ( e ) ,$$

wherein e is the probability that frames corresponding to the next packets of the first and second packet streams S1, S2 to be transmitted are lost during transmission (i.e., unplayable). Hence, e can be described as follows:

e=e_{loss,1}×e_{loss,2}=(Pₙ₁+(1−Pₙ₁)×P_{b1})×(Pₙ₂+(1−Pₙ₂)×P_{b2})

wherein:
e_{loss,1} is the probability of the next packet of the first packet stream S1 being lost, e_{loss,2} is the probability of the next packet of the second packet stream S2 being lost,
Pₙ₁ is the probability of the next packet of the first packet stream S1 being lost due to network loss, Pₙ₂ is the probability of the next packet of the second packet stream S2 being lost due to network loss, P_{b1} is the probability of the next packet of the first packet stream S1 being lost due to late arrival, P_{b2} is the probability of the next packet of the second packet stream S2 being lost due to late arrival,
(1−Pₙ₁)×P_{b1} is the probability of the next packet of the first packet stream S1 being lost due to late arrival given that the packet is not lost during transmission, and (1−Pₙ₂)×P_{b2} is the probability of the next packet of the second packet stream S2 being lost due to late arrival given that the packet is not lost during transmission.

It is to be noted that P_{b1} and P_{b2} are related to F_{D,s}(d_{play,i}) according to the mathematical relation of P_{bs}=1−F_{D,s}(d_{play,i})=1−F_{D,s}(\hat{d}_{i,s}+β\hat{ν}_{i,s}). The network delay cumulative function F_{D,s}(d_{play,i}) represents the probability that the next packet to be transmitted is received by the receiving terminal 200 and is processed by the receiving terminal 200 within the duration of the playout delay d_{play,i}. Thus, P_{bs} is the probability that the packet is not received by the receiving terminal 200 within the duration of the playout delay d_{play,i}.

Therefore, (1−e) is the probability that frames generated by the MD decoder 23 from the next packets to be transmitted are playable. Next, given that the frames are playable, the probability that the frames are generated from the corresponding packets of both of the packet streams S1, S2 is

$${ρ}_{1} = \frac{Pr \{ {Ω}_{1} \}}{Pr \{ {Ω}_{1} ⋃ {Ω}_{2} \}} = \frac{( 1 - {e}_{loss , 1} ) \times ( 1 - {e}_{loss , 2} )}{( 1 - e )} ,$$

and the probability that the frames are generated from the corresponding packets of only one of the packet streams S1, S2 is

$${ρ}_{2} = \frac{Pr \{ {Ω}_{2} \}}{Pr \{ {Ω}_{1} ⋃ {Ω}_{2} \}} = 1 - {ρ}_{1} .$$

Using results obtained from a nonlinear regression model, voice quality impairment due to packet encoding and packet loss can be described as follows:

I_{e,j}(r,e)=I_{codec,j}(r)+I_{pl,j}(e)=γ_{1,j}+γ_{2,j} ln(1+γ_{3,j}e),

wherein:
γ_{1,j} is an impairment factor corresponding to voice quality impairment due to packet encoding, and is inversely proportional to a coding rate (r) according to an encoding and loss impairment prediction model I_{codec,j}(r), and
γ_{2,j} and γ_{3,j} are impairment factors corresponding to voice quality impairment due to packet loss, and are related to I_{pl,j}(e) in the mathematical relation of γ_{2,j} ln(1+γ_{3,j}e).

Moreover, the impairment factors γ₁, γ₂, and γ₃ can be obtained by a conventional value analysis method. Table 1 shows different combinations of values of γ₁, γ₂, and γ₃ corresponding to different combinations of packet-receiving conditions and coding standards (MD-G.729a and MD-AMR).

TABLE 1

| Codec | γ₁, γ₂, γ₃ |
|---|---|
| MD-G.729a (Ω₁) | 21.962, 17.016, 16.088 |
| MD-G.729a (Ω₂) | 52.6143, 191870, 2.08 × 10⁻⁴ |
| MD-AMR (Ω₁) | 20.084, 22.958, 17.32 |
| MD-AMR (Ω₂) | 53.751, 111307, 6.06 × 10⁻⁴ |

Subsequently, the obtained values of ρ₁, ρ₂, I_{e,1}(e), and I_{e,2}(e) are substituted into the encoding and loss impairment prediction model Iₑ(e) as follows,

Iₑ(e)=I_{e,temp}=ρ₁×I_{e,1}(e)+ρ₂×I_{e,2}(e),

so as to obtain a corresponding encoding and loss impairment prediction value.

After the values of the delay impairment prediction model I_{D}(D) and the encoding and loss impairment prediction model Iₑ(e) are obtained, the playout scheduling module 16 is configured to determine an optimum value of β, and to provide the optimum value of β to the MD decoder 23 such that the MD decoder 23 can generate the recovered frames from next packets according to the optimal value of β.

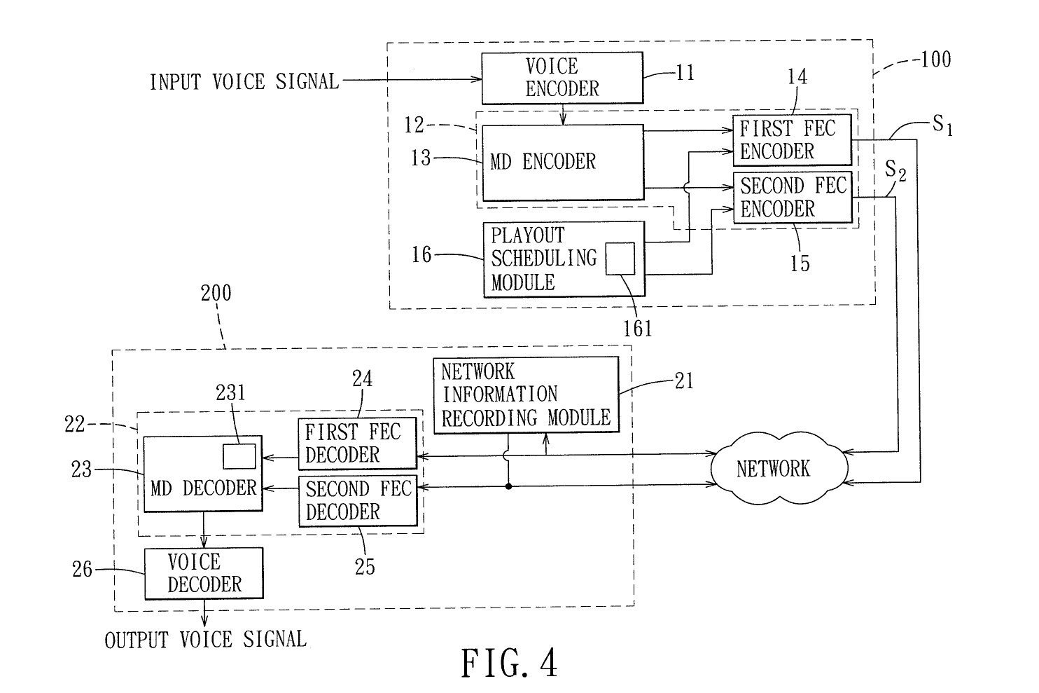

Referring to FIG. 4, the second preferred embodiment of a multi-stream voice transmission system according to the present invention is similar to the first preferred embodiment, and employs Forward Error Correction (FEC) protection.

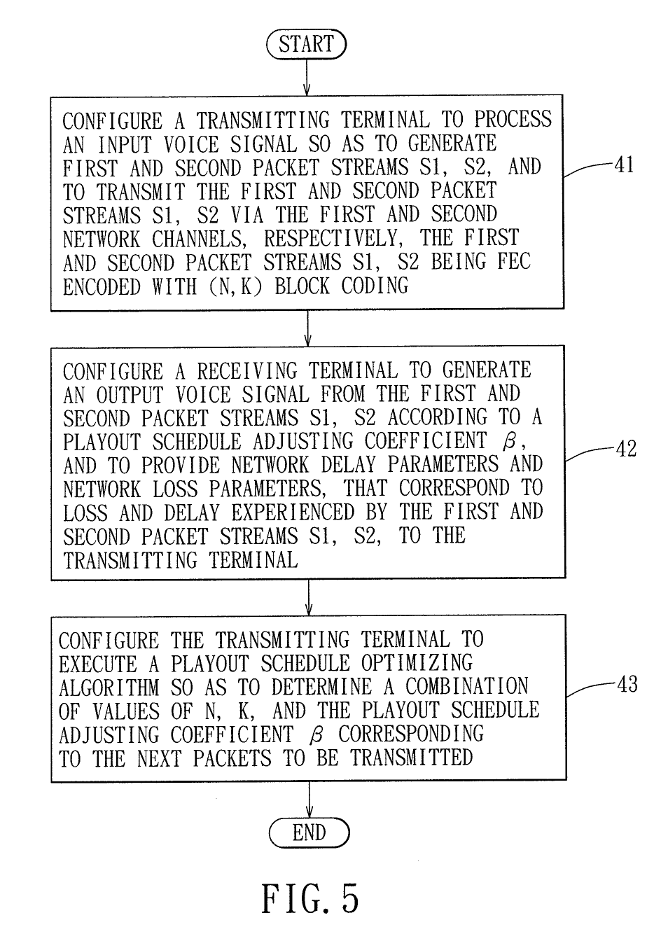

Moreover, the multi-stream voice transmission system of the second preferred embodiment is configured to perform the second preferred embodiment of a voice quality optimization scheme according to the present invention (shown in FIG. 5).

In the second preferred embodiment, the MD encoder 13 of the MD encoding unit 12 is for encoding the source frames into first and second encoded MD packet streams. The MD encoding unit 12 further includes first and second FEC encoders 14, 15 that are coupled to the MD encoder 13. In Step 41 of the voice quality optimization scheme, the first and second FEC encoders 14,15 perform FEC encoding upon the first and second encoded MD packet streams so as to generate the first and second packet streams at packetization intervals (Tₚ), respectively. It is to be noted that the first and second FEC encoders 14, 15 contribute to the coding delay (dc).

The first and second FEC encoders 14, 15 employ (N, K) block coding such that each of which generates (N−K) check packets for every K packets received from a respective one of the first and second MD packet streams, and appends the (N−K) check packets to the K packets, for which the (N−K) check packets are generated, to form a FEC block having a length of N packets. Thus, each of the first and second FEC encoders 14, 15 outputs a respective one of the first and second packet streams S1, S2 including a plurality of FEC blocks each of which has a length of N packets.

Moreover, if at least K packets of a FEC block are successfully received by the receiving terminal 200, other lost packets of the FEC block can be recovered. The first and second FEC encoders 14, 15 of the present embodiment are Reed-Solomon (RS) encoders, which are capable of correcting (N−K)/2 lost packets, or even (N−K) lost packets if the exact locations of the lost packets in the FEC block are known.

In the second preferred embodiment, the MD decoding unit 22 of the receiving terminal 200 further includes first and second FEC decoders 24, 25 for receiving the first and second packet streams S1, S2, and for performing FEC decoding upon the first and second packet streams S1, S2 received via the first and second network channels so as to generate first and second decoded MD packet streams, respectively.

In Step 42 of the voice quality optimization scheme, the playout buffer 231 of the MD decoder 23 is coupled to the first and second FEC decoders 24, 25 for receiving packets of the first and second decoded MD packet streams and for buffering the packets of the first and second decoded MD packet streams. Subsequently, the MD decoder 23 generates a plurality of recovered frames from the packets buffered by the playout buffer 231 according to a playout schedule adjusting coefficient (β) received from the playout scheduling module 16.

The playout delay d_{play,i} in the second preferred embodiment includes the delay introduced by the FEC encoding process, and is described as follows:

d_{play,i}=\hat{d}ᵢ+β\hat{ν}ᵢ+(N−1)×Tₚ,

wherein (N−1)×Tₚ is the delay introduced by the FEC encoding process.

In Step 43 of the voice quality optimization scheme, the playout scheduling module 16 of the second preferred embodiment is configured to obtain, from the network delay parameters, the network loss parameters, and the coding delay (dc), a combination of values of N, K, and the playout schedule adjusting coefficient (β) corresponding to a next talkspurt to be transmitted. Furthermore, N, K, and the playout schedule adjusting coefficient (β) obtained by the playout scheduling module 16 have values within corresponding preset ranges that result in a maximum value of the quality parameter (R) and that satisfy a condition that a product of N/K and MD coding gain is less than 2 and a condition that K is greater than a number of packets of the next talkspurt to be transmitted.

Therefore, the algorithm in the second preferred embodiment can be described as follows:

Initial: R₁=0; R₂=0;

FOR K_{search}=1:1:Kₘₐₓ//K_{search}=1, 2, 3, . . . , Kₘₐₓ; e.g., Kₘₐₓ=8

FOR N_{search}=K_{search}+1:1:Nₘₐₓ//N_{search}=K_{search}+1, K_{search}+2, . . . , Nₘₐₓ; e.g., Nₘₐₓ=15

IF (N_{search}/K_{search})×(MD coding gain)<2 //enters the “if loop” if the condition of FEC encoding is met
//uses the network delay parameters of the first FEC packet stream S1, namely \hat{d}_{i,1} and \hat{ν}_{i,1}

D=d_{play,i}+dc=\hat{d}_{i,1}+β_{search}×\hat{ν}_{i,1}+(N_{search}−1)×Tₚ+dc

I_{d}(D)=0.024D+0.11(D−177.3)H(D−177.3)

I_{e,temp}=Iₑ(N_{search},K_{search},β_{search},p₁,q₁,F_{D,1}(D),(k₁,g₁),p₂,q₂,F_{D,2}(D),(k₂,g₂),\hat{d}_{i,1},\hat{ν}_{i,1)}

//obtains an encoding and loss impairment prediction value using an averaged encoding and loss impairment prediction model Iₑ (e), the description of which is given hereinafter

```
R₁_temp=94.2−I_{d}(D)−I_{e,temp}
IF R₁_temp>R_{1′}
  R₁=R₁_temp;
  N_ 1 = N_{search}; K_ 1 = K_{search}; β_ 1 = β_{search};
END IF
  D = \hat{d}_{i,2} + β_{search} × \hat{v}_{i,2} + (N_{search} − 1) × Tₚ + dc
  I_{d}(D)=0.024D+0.11(D−177.3)H(D−177.3)
  I_{e,temp} = Iₑ(N_{search}, K_{search}, β_{search}, p₁, q₁, F_{D,1}(D) ,
  (k₁, g₁) , p₂, q₂, F_{D,2}(D) , (k₂, g₂) , \hat{d}_{i,2}, \hat{v}_{i,2)}
  R₂_temp=94.2−I_{D} (D)−I_{e,temp}
  IF R₂_temp>R₂
    R₂=R₂_temp;
    N_ 2 = N_{search}; K_ 2 = K_{search}; β_ 2 = β_{search};
  END IF
END IF
END
END
```

END //the algorithm has found two combinations of N, K, and the playout scheduling adjusting coefficient (β) ([N_{—}_{¹}, K_{—}_{¹}, β_{—}_{¹}] and [N_{—}_{²}, K_{—}_{²}, β_{—}_{²}]) corresponding to the next talkspurt to be transmitted; however, the same playout schedule adjusting coefficient (β) must be used for processing the first and second packet streams S1, S2; therefore, the subsequent step involves choosing one of the two combinations

IF R₁>R₂//if R₁ is greater than R₂
(N, K, β)=(N_{—}_{¹}, K_{—}_{¹}, β_{—}_{¹}) // chooses the combination corresponding to the first packet stream S1 [N_{—}_{¹}, K_{—}_{¹}, β_{—}_{¹}]
d_{play,i}=\hat{d}_{i,1}+β×\hat{ν}_{i,1}+(N−1)×Tₚ //obtain a playout delay d_{play,i} corresponding to N_{—}_{¹},K_{—}_{¹}, and β_{—}_{¹}

ELSE //or else
(N, K, β)=(N_{—}_{²}, K_{—}_{²}, β_{—}_{²})// chooses the combination corresponding to the second packet stream S2 [N_{—}_{²}, K_{—}_{²}, β_{—}_{²}]
d_{play,i}=\hat{d}_{i,2}+β×\hat{ν}_{i,2}+(N−1)×Tₚ//obtain a playout delay d_{play,i} corresponding to N_{—}_{²},K_{—}_{²}, and β_{—}_{²}

END IF

After executing the program, the playout scheduling module 16 is further configured to provide the optimal values of N, K to the first and second FEC encoders 14, 15, and the playout schedule adjusting coefficient β obtained thereby to the MD decoder 23 to perform MD decoding upon packets of the next talkspurt.

### Determining Value of Iₑ:

In the second preferred embodiment, the encoding and loss impairment prediction model Iₑ is an averaged impairment model corresponding to K packets of the next talkspurt to be transmitted, and is described as follows:

$${I}_{e} = \frac{1}{K} {\sum }_{i = 1}^{K} {\sum }_{j = 1}^{2} {ρ}_{j} ( i ) {I}_{e , j} ( e ) , \\ e = {\prod }_{s = 1}^{2} {P}_{FEC , s} ( i ) , \qquad ( 1 )$$

wherein:
ρ₁(i) is the probability of the playout buffer 231 of the MD decoder 23 successfully receiving the i^{th} packet of each of the first and second packet streams S1, S2 (j=1),
ρ₂(i) is the probability of the playout buffer 231 of the MD decoder 23 unsuccessfully receiving the i^{th} packet of one of the first and second packet streams S1, S2 (j=2),
I_{e,1}(e) is an encoding and loss impairment prediction factor, and is for describing voice quality impairment of a talkspurt due to packet encoding and packet loss when the MD decoder 23 successfully receives the i^{th} packet of each of the first and second packet streams S1, S2 generated from the talkspurt (j=1),
I_{e,2}(e) is an encoding and loss impairment prediction factor, and is for describing voice quality impairment of a talkspurt due to packet encoding and packet loss when the MD decoder 23 unsuccessfully receives the i^{th} packet of one of the first and second packet streams S1, S2 generated from the talkspurt (j=2), and
e is the probability of the i^{th} packet of each of the first and second packet streams S1, S2, that are generated from the talkspurt, being lost during the transmission over the first and second network channels.

Furthermore, ρⱼ(i) can be further described as follows:

$${ρ}_{1} ( i ) = {P}_{r} ( {Ω}_{1} \vert {Ω}_{1} ⋃ {Ω}_{2} )$$

$${ρ}_{1} ( i ) = \frac{{P}_{r} ( {Ω}_{1} , {Ω}_{1} ⋃ {Ω}_{2} )}{{P}_{r} ( {Ω}_{1} ⋃ {Ω}_{2} )}$$

$${ρ}_{1} ( i ) = \frac{{\prod }_{s = 1}^{2} ( 1 - {P}_{FEC , s} ( i ) )}{1 - {\prod }_{s = 1}^{2} ( {P}_{FEC , s} ( i ) )}$$

$${ρ}_{2} ( i ) = 1 - {ρ}_{1} ( i )$$

wherein:
Pᵣ(Ω₁|Ω₁∪Ω₂) is the probability that the receiving terminal 200 successfully receives the i^{th} packets of the first and second packet streams S1, S2,
Pᵣ(Ω₁∪Ω₂) is the probability that the frames generated from the i^{th} packets of the first and second packet streams S1, S2 are playable, and
P_{FEC,s}(i) is the probability of a packet being unrecoverable from late arrival or network loss.

Moreover, P_{FEC,s}(i) can be described as follows:

$${P}_{FEC , s} ( i ) = \frac{{p}_{s}}{\underbrace{{p}_{s} + {q}_{s}}_{network loss}} ( 1 - {P}_{REC 1 , s} ( i ) ) + \underbrace{\frac{{q}_{s}}{{p}_{s} + {q}_{s}} ( 1 - {F}_{D , s} ( {D}_{FEC , i} ) )}_{late arrival loss} ( 1 - {P}_{REC 2 , s} ( i ) )$$

$${D}_{FEC , i} = {\hat{d}}_{i , s} + β {\hat{v}}_{i , s} + ( N - i ) {T}_{p} ,$$

wherein:
F_{D,S}(D_{FEC,i}) is the probability that the network delay experienced by the i^{th} packet is shorter than D_{FEC,i}, and
each of P_{REC1,s}(i) and P_{REC2,s}(i) is the probability that the i^{th} packet of the respective one of the first and the second packet streams S1, S2 is FEC-recoverable from late arrival or network loss.

P_{REC1,s}(i) and P_{REC2,s}(i) are described as follows:

$${P}_{REC 1 , s} ( i ) = {\sum }_{L - 1}^{N - K} {\sum }_{m = 0}^{min ( L - 1 , i - 1 )} {\tilde{R}}_{s}^{′} ( m + 1 , i , {D}_{FEC , i} ) {R}_{s}^{′} ( L - m , N - i + 1 , {D}_{FEC , i} )$$

$${P}_{REC 2 , s} ( i ) = {\sum }_{L - 1}^{N - K} {\sum }_{m = 0}^{min ( L - 1 , i - 1 )} {\tilde{S}}_{s}^{′} ( i + 1 , i , {D}_{FEC , i} ) {S}_{s}^{′} ( N - i - L + m + 2 , N - i + 1 , {D}_{FEC , i} )$$

wherein:
Rₛ′(m, n, D_{FEC,i}) is the probability that (m−1) of (n−1) consecutive packets following the i^{th} packet of the s^{th} packet stream experience network loss or late arrival given that the i^{th} packet is lost,
\tilde{R}_{S}′(m, n, D_{FEC,i}) is the probability that (m−1) of (n−1) consecutive packets preceding the i^{th} packet of the s^{th} packet stream experience network loss or late arrival given that the i^{th} packet is lost,
Sₛ′(m, n, D_{FEC,i}) is the probability of receiving (m−1) of (n−1) consecutive packets following the i^{th} packet of the s^{th} packet stream given that the i^{th} packet is successfully received,
\tilde{S}ₛ′(m, n, D_{FEC,i}) is the probability of receiving (m−1) of (n−1) consecutive packets preceding the i^{th} packet of the s^{th} packet stream given that the i^{th} packet is successfully received.

The mathematical basis of P_{REC1,s}(i) and P_{REC2,s}(i) are obtained through modifying content of “ADAPTIVE JOINT PLAYOUT BUFFER PLAYOUT BUFFER AND FEC ADJUSTMENT FOR INTERNET TELEPHONY” published in Technical Report IC/2002/35.

Hence, values of ρ₁(i), ρ₂(i) and

$${\prod }_{s = 1}^{2} {P}_{FEC , s} ( i )$$

can be obtained given values of N, K, the playout schedule adjusting coefficient (β), and the relevant network parameters.

Similar to the first preferred embodiment, the same non-linear regression analysis is used to obtain an encoding and loss impairment prediction model

I_{e,j}(e)=γ_{1,j}+γ_{2,j} ln(1+γ_{3,j}e),j=1,2,

wherein:

I_{e,1} is an impairment prediction value for describing quality impairment of the output voice signal caused by packet encoding and packet loss of successfully receiving the corresponding packets of each of the first and second packet streams S1, S2 (Ω₁),

I_{e,2} represents the impairment prediction value for describing quality impairment of the output voice signal caused by packet encoding and packet loss of successfully receiving the corresponding packets of only one of the first and second packet streams S1, S2 (Ω₂), and

the impairment factors γ_{1,j}, γ_{2,j}, and γ_{3,j} can be obtained from Table 1.

Finally, the obtained values of ρ₁, ρ₂, I_{e,1}(e), and I_{e,2}(e) are substituted into the encoding and loss impairment prediction model Iₑ so as to obtain an encoding and loss impairment prediction value corresponding to the next talkspurt to be transmitted.

Subsequently, the playout scheduling module 16 obtains a combination of N, K, and the playout schedule adjusting coefficient β, provides the values of N and K to the first and second FEC encoders 14, 15, and provides the value of the playout schedule adjusting coefficient (β) to the MD decoder 23.

In summary, the network information recording module 21 is configured to record information regarding network delay and network loss experienced by packets of the first and second packet streams S1, S2 transmitted via the first and second network channels, to generate the network delay parameters and the network loss parameters from the recorded information, and to provide the network delay parameters and the network loss parameters to the playout scheduling module 16. The playout scheduling module 16 is configured to implement the playout schedule optimization algorithm using the received parameters so as to generate an optimal combination of N, K, and the playout schedule adjusting coefficient (β) that results in a balance between the predicted network loss and the predicted playout delay d_{play,i} of the next talkspurt to be transmitted. The playout scheduling module 16 is further configured to provide the values of N and K to the first and second FEC encoders 14, 15, and to provide the value of the playout schedule adjusting coefficient (β) to the MD decoder 23 such that the MD decoder 23 can generate the recovered frames corresponding to the next talkspurt to be transmitted.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A multi-stream voice transmission system adapted for transmitting and receiving voice signals through first and second network channels, comprising:
a transmitting terminal configured to process an input voice signal so as to generate first and second packet streams, and to transmit the first and second packet streams via the first and second network channels, respectively, said transmitting terminal including
a voice encoder for encoding the input voice signal into a plurality of source frames,
a multiple description (MD) encoding unit for encoding the source frames into the first and second packet streams, said MD encoding unit including a MD encoder, and
a playout scheduling module configured to obtain a playout schedule adjusting coefficient (β) corresponding to the first and second packet streams to be transmitted; and
a receiving terminal configured to receive the first and second packet streams transmitted by said transmitting terminal via the first and second network channels, to process the first and second packet streams so as to generate an output voice signal, and to receive the playout schedule adjusting coefficient (β) from said transmitting terminal, said receiving terminal including
a network information recording module for recording information regarding network delay and network loss experienced by the packets in the first and second packet streams transmitted via the first and second network channels, for generating network delay parameters and network loss parameters according to the recorded information, and for providing the network delay parameters and the network loss parameters to said playout scheduling module of said transmitting terminal,
a MD decoding unit for receiving the first and second packet streams, said MD decoding unit including a MD decoder, said MD decoder including a playout buffer for buffering packets corresponding to the first and second packet streams, said MD decoder generating a plurality of recovered frames from the packets buffered by said playout buffer according to the playout schedule adjusting coefficient (β) received from said transmitting terminal, and
a voice decoder for generating the output voice signal from the recovered frames;
wherein said voice encoder and said MD encoding unit of said transmitting terminal collectively introduce a coding delay (dc) to the multi-stream voice transmission system;
wherein the playout schedule adjusting coefficient (β) obtained by said playout scheduling module has a value within a preset range that results in a maximum value of a quality parameter (R), the quality parameter (R) being equal to 94.2−Iₑ−I_{D}(D);
wherein Iₑ is a function of the playout schedule adjusting coefficient (β), and the network delay parameters and the network loss parameters received from said receiving terminal; and
wherein I_{D}(D) is a function of the coding delay (dc), the playout schedule adjusting coefficient (β), and the network delay parameters.

2. The multi-stream voice transmission system as claimed in claim 1, wherein:
said MD encoder of said MD encoding unit is for encoding the source frames into first and second encoded MD packet streams;
said MD encoding unit of said transmitting terminal further includes first and second forward error correction (FEC) encoders coupled to said MD encoder for performing FEC encoding upon the first and second encoded MD packet streams so as to generate the first and second packet streams at packetization intervals (Tₚ), respectively, each of the first and second packet streams including a plurality of FEC blocks, each of the FEC blocks including K packets and (N−K) check packets that are generated for the K packets;
said MD decoding unit of said receiving terminal further includes first and second FEC decoders for performing FEC decoding upon the first and second packet streams received via the first and second network channels so as to generate first and second decoded MD packet streams, respectively;
said playout buffer of said MD decoder is coupled to said first and second FEC decoders for receiving the first and second decoded MD packet streams and for buffering the first and second decoded MD packet streams;
the input voice signal is constituted by a plurality of talkspurts with a silence period between temporally adjacent ones of the talkspurts;
said playout scheduling module is configured to obtain, from the network delay parameters, the network loss parameters and the coding delay (dc), a combination of values of N, K and the playout schedule adjusting coefficient (β) corresponding to the first and second packet streams to be transmitted, wherein N, K and the playout schedule adjusting coefficient (β) obtained by said playout scheduling module have values within corresponding preset ranges that result in the maximum value of the quality parameter (R) and that satisfy a condition that a product of N/K and MD coding gain is less than 2 and a condition that K is greater than a number of packets of the next talkspurt to be transmitted;
Iₑ is a function of N, K, the playout schedule adjusting coefficient (β), the network delay parameters, and the network loss parameters;
I_{D}(D) is a function of N, the packetization interval (Tₚ), the playout schedule adjusting coefficient (β), the coding delay (dc) and the network delay parameters; and
said playout scheduling module is configured to provide N and K obtained thereby to said first and second FEC encoders.

3. The multi-stream voice transmission system as claimed in claim 2, wherein:
the network delay parameters include Pareto distribution parameters kₛ and gₛ, a network delay cumulative function F_{D,S}(D), an estimated network delay \hat{d}_{i,s}, and an estimated network delay variation \hat{ν}_{i,s}; and
the network loss parameters include Gilbert channel model parameters pₛ and qₛ.

4. The multi-stream voice transmission system as claimed in claim 3, wherein said MD decoder is configured to generate the recovered frames from the packets buffered by said playout buffer thereof according to a playout delay d_{play,i}=\hat{d}ᵢ+β\hat{ν}ᵢ+(N−1)Tₚ, wherein D=d_{play,i}+dc.

5. The multi-stream voice transmission system as claimed in claim 4, wherein I_{D}(D)=0.024D+0.11(D−177.3)H(d−177.3), and H is a step function.

6. The multi-stream voice transmission system as claimed in claim 3, wherein
$${I}_{e , avg} = \frac{1}{K} {\sum }_{i = 1}^{K} {\sum }_{j = 1}^{2} {ρ}_{j} ( i ) {I}_{e , j} ( e ) , \\ e = {\prod }_{s = 1}^{2} {P}_{FEC , s} ( i ) ,$$
ρ₁(i) is the probability of said playout buffer of said MD decoder successfully receiving the i^{th} packet of each of the first and second packet streams (j=1),
ρ₂(i) is the probability of said playout buffer of said MD decoder unsuccessfully receiving the i^{th} packet of one of the first and second packet streams (j=2), ρ₁(i) and ρ₂(i) being related to each other by the mathematical relation of ρ₂(i)=1−ρ₁(i),
I_{e,1}(e) is an encoding and loss impairment prediction factor, and is for describing voice quality impairment of a talkspurt due to packet encoding and packet loss when said MD decoder successfully receives the i^{th} packet of each of the first and second packet streams generated from the talkspurt (j=1),
I_{e,2}(e) is an encoding and loss impairment prediction factor, and is for describing voice quality impairment of a talkspurt due to packet encoding and packet loss when said MD decoder unsuccessfully receives the i^{th} packet of one of the first and second packet streams generated from the talkspurt (j=2), and
e is the probability of the i^{th} packet of each of the first and second packet streams, that are generated from the talkspurt, being lost during the transmission over the first and second network channels.

7. The multi-stream voice transmission system as claimed in claim 6, wherein
I_{e,1}(e)=γ_{1,1}+γ_{2,1} ln(1+γ_{3,1}e),
I_{e,2}(e)=γ_{1,2}+γ_{2,2} ln(1+γ_{3,2}e),
γ_{1,1} and γ_{1,2} describe voice quality impairment due to packet encoding, and
γ_{2,1}, γ_{3,1}, γ_{2,2}, and γ_{3,2} describe voice quality impairment due to packet loss.

8. A multi-stream voice transmission method for transmitting and receiving voice signals through first and second network channels, comprising:
(A) configuring a transmitting terminal to process an input voice signal so as to generate first and second packet streams, and to transmit the first and second packet streams via the first and second network channels, respectively, including
(A1) configuring the transmitting terminal to perform voice encoding so as to encode the input voice signal into a plurality of source frames,
(A2) configuring the transmitting terminal to the source frames into the first and second packet streams, the encoding in sub-step (A2) including multiple description (MD) encoding, and
(A3) configuring the transmitting terminal to obtain a playout schedule adjusting coefficient (β) corresponding to the first and second packet streams to be transmitted; and
(B) configuring a receiving terminal to receive the first and second packet streams transmitted by the transmitting terminal via the first and second network channels, to process the first and second packet streams so as to generate an output voice signal, and to receive the playout schedule adjusting coefficient (β) from the transmitting terminal, including
(B1) configuring the receiving terminal to record information regarding network delay and network loss experienced by packets in the first and second packet streams transmitted via the first and second network channels, to generate network delay parameters and network loss parameters according to the recorded information, and to provide the network delay parameters and the network loss parameters to the transmitting terminal,
(B2) configuring the receiving terminal to buffer packets corresponding to the first and second packet streams in a playout buffer, and to perform MD decoding of the packets buffered by the playout buffer according to the playout schedule adjusting coefficient (β) obtained from the transmitting terminal so as to generate a plurality of recovered frames, and
(B3) configuring the receiving terminal to perform voice decoding for generating the output voice signal from the recovered frames;
wherein, in step (A), the transmitting terminal introduces a coding delay (dc);
wherein, in sub-step (A3), the playout schedule adjusting coefficient (β) obtained by the transmitting terminal has a value within a preset range that results in a maximum value of a quality parameter (R), the quality parameter (R) being equal to 94.2−Iₑ−I_{D}(D);
wherein Iₑ is a function of the playout schedule adjusting coefficient (β), and the network delay parameters and the network loss parameters received by the transmitting terminal from the receiving terminal; and
wherein I_{D}(D) is a function of the coding delay (dc), the playout schedule adjusting coefficient (β), and the network delay parameters.

9. The multi-stream voice transmission method as claimed in claim 8, wherein:
in sub-step (A2), the source frames are encoded into first and second encoded MD packet streams;
the encoding in sub-step (A2) further includes forward error correction (FEC) encoding upon the first and second encoded MD packet streams so as to generate the first and second packet streams at packetization intervals (Tₚ), respectively, each of the first and second packet streams including a plurality of FEC blocks, each of the FEC blocks including K packets and (N−K) check packets that are generated for the K packets;
sub-step (B2) further includes performing FEC decoding upon the first and second packet streams received via the first and second network channels so as to generate first and second decoded MD packet streams, respectively;
in sub-step (B2), the playout buffer receives the first and second decoded MD packet streams for buffering the first and second decoded MD packet streams;
in sub-step (A1), the input voice signal is constituted by a plurality of talkspurts with a silence period between temporally adjacent ones of the talkspurts;
in sub-step (A3), the transmitting terminal is configured to obtain, from the network delay parameters, the network loss parameters and the coding delay (dc), a combination of values of N, K and the playout schedule adjusting coefficient (β) corresponding to the first and second packet streams to be transmitted, wherein N, K and the playout schedule adjusting coefficient (β) obtained by the transmitting terminal have values within corresponding preset ranges that result in the maximum value of the quality parameter (R) and that satisfy a condition that a product of N/K and MD coding gain is less than 2 and a condition that K is greater than a number of packets of the next talkspurt to be transmitted;
Iₑ is a function of N, K, the playout schedule adjusting coefficient (β), the network delay parameters, and the network loss parameters;
I_{D}(D) is a function of N, the packetization interval (Tₚ), the playout schedule adjusting coefficient (β), the coding delay (dc) and the network delay parameters.

10. The multi-stream voice transmission method as claimed in claim 9, wherein:
the network delay parameters include Pareto distribution parameters kₛ and gₛ, a network delay cumulative function F_{D,S}(D), an estimated network delay \hat{d}_{i,s}, and an estimated network delay variation \hat{ν}_{i,s}; and
the network loss parameters include Gilbert channel model parameters pₛ and qₛ.

11. The multi-stream voice transmission method as claimed in claim 10, wherein, in sub-step (B2), the receiving terminal is configured to generate the recovered frames from the packets buffered by the playout buffer thereof according to a playout delay d_{play,i}=\hat{d}ᵢ+β\hat{ν}ᵢ+(N−1)Tₚ, wherein D=d_{play,i}+dc.

12. The multi-stream voice transmission method as claimed in claim 11, wherein I_{D}(D)=0.024D+0.11(D−177.3)H(d−177.3), and H is a step function.

13. The multi-stream voice transmission method as claimed in claim 10, wherein
$${I}_{e , avg} = \frac{1}{K} {\sum }_{i = 1}^{K} {\sum }_{j = 1}^{2} {ρ}_{j} ( i ) {I}_{e , j} ( e ) , \\ e = {\prod }_{s = 1}^{2} {P}_{FEC , s} ( i ) ,$$
ρ₁(i) is the probability of the playout buffer successfully receiving the i^{th} packet of each of the first and second packet streams (j=1),
ρ₂(i) is the probability of the playout buffer unsuccessfully receiving the i^{th} packet of one of the first and second packet streams (j=2), ρ₁(i) and ρ₂(i) being related to each other by the mathematical relation of ρ₂(i)=1−ρ₁(i),
I_{e,1}(e) is an encoding and loss impairment prediction factor, and is for describing voice quality impairment of a talkspurt due to packet encoding and packet loss when the receiving terminal successfully receives the i^{th} packet of each of the first and second packet streams generated from the talkspurt (j=1),
I_{e,2}(e) is an encoding and loss impairment prediction factor, and is for describing voice quality impairment of a talkspurt due to packet encoding and packet loss when the receiving terminal unsuccessfully receives the i^{th} packet of one of the first and second packet streams generated from the talkspurt (j=2), and
e is the probability of the i^{th} packet of each of the first and second packet streams, that are generated from the talkspurt, being lost during the transmission over the first and second network channels.

14. The multi-stream voice transmission method as claimed in claim 13, wherein
Ie,1(e)=γ1,1+γ2,1 ln(1+γ3,1e),
Ie,2(e)=γ1,2+γ2,2 ln(1+γ3,2e),
γ1,1 and γ1,2 describe voice quality impairment due to packet encoding, and
γ2,1, γ3,1, γ2,2, and γ3,2 describe voice quality impairment due to packet loss.

15. A playout scheduling module for a transmitting terminal, the transmitting terminal being used together with a receiving terminal in a multi-stream voice transmission system for transmitting and receiving voice signals through first and second network channels,
the transmitting terminal being configured to perform voice encoding for encoding an input voice signal into a plurality of source frames, to perform multiple description (MD) encoding of the source frames so as to generate first and second packet streams, and to transmit the first and second packet streams via the first and second network channels, respectively,
the receiving terminal being configured to receive the first and second packet streams transmitted by the transmitting terminal via the first and second network channels, to record information regarding network delay and network loss experienced by packets in the first and second packet streams transmitted via the first and second network channels, to generate network delay parameters and network loss parameters according to the recorded information, to provide the network delay parameters and the network loss parameters to the transmitting terminal, to buffer packets corresponding to the first and second packet streams in a playout buffer, to perform MD decoding of the packets buffered by the playout buffer so as to generate a plurality of recovered frames, and to perform voice decoding of the recovered frames so as to generate an output voice signal,
the transmitting terminal introducing a coding delay (dc) to the multi-stream voice transmission system,
said playout scheduling module comprising a computing unit for obtaining a playout schedule adjusting coefficient (β) corresponding to the first and second packet streams to be transmitted, the playout schedule adjusting coefficient (β) having a value within a preset range that results in a maximum value of a quality parameter (R), the quality parameter (R) being equal to 94.2−Iₑ−I_{D}(D),
Iₑ being a function of the playout schedule adjusting coefficient (β), and the network delay parameters and the network loss parameters received by the transmitting terminal from the receiving terminal, and
I_{D}(D) being a function of the coding delay (dc), the playout schedule adjusting coefficient (β), and the network delay parameters,
wherein said computing unit is configured to output the playout schedule adjusting coefficient (β) for receipt by the receiving terminal such that the receiving terminal is operable to perform MD decoding of the packets buffered by the playout buffer according to the playout schedule adjusting coefficient (β) so as to generate the recovered frames.

16. The playout scheduling module as claimed in claim 15,
the transmitting terminal being configured to perform MD encoding so as to encode the source frames into first and second encoded MD packet streams, and to perform forward error correction (FEC) encoding upon the first and second encoded MD packet streams so as to generate the first and second packet streams at packetization intervals (Tₚ), respectively, each of the first and second packet streams including a plurality of FEC blocks, each of the FEC blocks including K packets and (N−K) check packets that are generated for the K packets,
the receiving terminal being configured to perform FEC decoding upon the first and second packet streams received via the first and second network channels so as to generate first and second decoded MD packet streams, respectively,
the playout buffer receiving the first and second decoded MD packet streams for buffering the first and second decoded MD packet streams,
the input voice signal being constituted by a plurality of talkspurts with a silence period between temporally adjacent ones of the talkspurts,
wherein said computing unit is configured to obtain, from the network delay parameters, the network loss parameters, and the coding delay (dc), a combination of values of N, K and the playout schedule adjusting coefficient (β) corresponding to the first and second packet streams to be transmitted, wherein N, K and the playout schedule adjusting coefficient (β) obtained by said computing unit have values within corresponding preset ranges that result in the maximum value of the quality parameter (R) and that satisfy a condition that a product of N/K and MD coding gain is less than 2 and a condition that K is greater than a number of packets of the next talkspurt to be transmitted;
Iₑ is a function of N, K, the playout schedule adjusting coefficient (β), the network delay parameters, and the network loss parameters; and
I_{D}(D) is a function of N, the packetization interval (Tₚ), the playout schedule adjusting coefficient (β), the coding delay (dc) and the network delay parameters.

17. The playout scheduling module as claimed in claim 16, wherein:
the network delay parameters include Pareto distribution parameters kₛ and gₛ, a network delay cumulative function F_{D,S}(D), an estimated network delay \hat{d}_{i,s}, and an estimated network delay variation \hat{ν}_{i,s}; and
the network loss parameters include Gilbert channel model parameters pₛ and qₛ.

18. The playout scheduling module as claimed in claim 17, wherein I_{D}(D)=0.024D+0.11(D−177.3)H(d−177.3), and H is a step function.

19. The playout scheduling module as claimed in claim 17, wherein
$${I}_{e , avg} = \frac{1}{K} {\sum }_{i = 1}^{K} {\sum }_{j = 1}^{2} {ρ}_{j} ( i ) {I}_{e , j} ( e ) , \\ e = {\prod }_{s = 1}^{2} {P}_{FEC , s} ( i ) ,$$
ρ₁(i) is the probability of the playout buffer successfully receiving the i^{th} packet of each of the first and second packet streams (j=1),
ρ₂(i) is the probability of the playout buffer unsuccessfully receiving the i^{th} packet of one of the first and second packet streams (j=2), ρ₁(i) and ρ₂(i) being related to each other by the mathematical relation of ρ₂(i)=1−ρ₁(i),
I_{e,1}(e) is an encoding and loss impairment prediction factor, and is for describing voice quality impairment of a talkspurt due to packet encoding and packet loss when the receiving terminal successfully receives the i^{th} packet of each of the first and second packet streams generated from the talkspurt (j=1),
I_{e,2}(e) is an encoding and loss impairment prediction factor, and is for describing voice quality impairment of a talkspurt due to packet encoding and packet loss when the receiving terminal unsuccessfully receives the i^{th} packet of one of the first and second packet streams generated from the talkspurt (j=2), and
e is the probability of the i^{th} packet of each of the first and second packet streams, that are generated from the talkspurt, being lost during the transmission over the first and second network channels.

20. The playout scheduling module as claimed in claim 19, wherein
I_{e,1}(e)=γ_{1,1}+γ_{2,1} ln(1+γ_{3,1}e),
I_{e,2}(e)=γ_{1,2}+γ_{2,2} ln(1+γ_{3,2}e),
γ_{1,1} and γ_{1,2} describe voice quality impairment due to packet encoding, and
γ_{2,1}, γ_{3,1}, γ_{2,2}, and γ_{3,2} describe voice quality impairment due to packet loss.
